(19) United States
(12) Patent Application Publication
(10) Pub. No.: US 2026/0204299 A1
(43) Pub. Date: Jul. 16, 2026

(54) PROCESSING OF TERNARY SYMBOLS

(71) Applicant: Infineon Technologies AG, Neubiberg (DE)

(72) Inventors: Thomas Kern, Aschheim (DE); Michael Goessel, Mahlow (DE); Alexander Glaetzer, Potsdam (DE)

(21) Appl. No.: 19/434,613

(22) Filed: Dec. 29, 2025

(30) Foreign Application Priority Data
Jan. 15, 2025 (DE) 10 2025 101 278.4

(51) Int. Cl. G11C 7/10; G11C 29/52

(52) U.S. Cl. CPC G11C 7/1069; G11C 7/1063; G11C 29/52

(57) ABSTRACT

An approach is proposed for processing a value that is determined from a set of N ternary memory cells, including the steps of: (i) reading the set of ternary memory cells and determining the ternary symbol H, M or L contained in the respective ternary memory cell; (ii) determining a first binary sequence based on the ternary symbols H of the set of read ternary memory cells; (iii) determining a second binary sequence based on the ternary symbols H and M of the set of memory cells; (iv) determining a third binary sequence based on the first and second binary sequence, wherein the number of bits of the third binary sequence is reduced compared with the number of bits of the first and second binary sequence, (v) determining a composite binary value based on the first binary sequence and the third binary sequence, and (vi) processing the composite binary value.

### REFERENCE TO RELATED APPLICATION

This Application claims the benefit of German Application number 10 2025 101 278.4, filed on Jan. 15, 2025, the contents of which are hereby incorporated by reference in their entirety.

### SUMMARY

It is known that more than two values can be stored in one memory cell. For example, three different physical states (also referred to as three symbols) can be stored in one memory cell. The three physical states are called trivalent symbols, ternary values or ternary symbols, and the associated memory cell is referred to as a trivalent memory cell or ternary memory cell.

Different physical values or values derived from different physical values can be determined during the read-out of a ternary memory cell. For example, different resistance values stored in a memory cell may result in different read currents during the readout. The obtained physical value, e.g. read current, can be compared with at least one reference value to determine which ternary symbol was stored in the memory cell.

It is also an option to take the time domain into account during the read-out in order to perform an assignment. In this respect, reference can be made, for example, to DE 10 2018 124 296 B4 or U.S. Pat. No. 9,805,771 B2. It is explained herein that a read current in a capacitor can be integrated into a voltage and the time until a voltage reaches a certain reference value can be determined.

One object is to deal efficiently with ternary memory cells and, in particular, to provide an efficient facility for binary processing of ternary symbols stored in ternary memory cells.

These examples proposed herein may be based on at least one of the following solutions. In particular, combinations of the following features can be used to achieve a desired result. The features of the device may be combined with features of the method or vice versa.

To achieve this object, a method is provided for processing a value determined from a set of N ternary memory cells comprising:
reading out the set of ternary memory cells and determining the ternary symbol H, M or L contained in the respective ternary memory cell,
determining a first binary sequence based on the ternary symbols H of the set of read ternary memory cells,
determining a second binary sequence based on the ternary symbols H and M of the set of read ternary memory cells,
determining a third binary sequence based on the first binary sequence and the second binary sequence, wherein the number of bits of the third binary sequence is reduced compared with the number of bits of the first binary sequence and the second binary sequence,
determining a composite binary value based on the binary coded first binary sequence and the binary coded third binary sequence,
processing the composite binary value.

It should be noted that the ternary symbols H, M and L are used for distinguishing purposes and generally indicate a first, second and third ternary symbol.

The respective ternary symbol can be determined depending on (at least) one physical value. It is also possible that the respective ternary symbol is determined by a value derived from a physical value.

During the readout of the set of N ternary memory cells, a sequence of N ternary symbols is thus obtained, wherein each of the ternary symbols has a position within the N ternary symbols determined by the sequence. These positions are taken into account in determining the first binary sequence and the second binary sequence. For example, if the third ternary symbol within the sequence of N ternary symbols is a ternary symbol H, the result is that the third bit of the first binary sequence has the value 1.

In one aspect, determining the first binary sequence comprises: determining the first binary sequence, wherein the binary value 1 is assigned only to the ternary memory cell having the ternary symbol H, and the binary value 0 is assigned to the remaining ternary memory cells having either the ternary symbol M or the ternary symbol L.

It should be noted that, generally speaking, the “value 0” represents a first binary value and the “value 1” represents a second binary value that is different from the first binary value (i.e. inverse to it).

In one aspect, determining the second binary sequence comprises: determining the second binary sequence, wherein the binary value 1 is assigned to the ternary memory cells having the ternary symbol H or the ternary symbol M, and the binary value 0 is assigned to the remaining ternary memory cells having the ternary symbol L.

In one aspect, determining the third binary sequence comprises: determining the third binary sequence, wherein the third binary sequence is determined from the bits of the second binary sequence at the position of which the bits of the first binary sequence are equal to 0.

The third binary sequence is therefore reduced by a number of bits on which the first binary sequence is equal to 1.

In one aspect, determining the third binary sequence comprises: determining the third binary sequence by removing from the second binary sequence the at least one bit for which the value 1 was determined in the first binary sequence.

In one aspect, in the error-free case, the first binary sequence is a code word of a first error code.

In one aspect, the first error code is an NH-from-N code, where NH is the number of ternary values H in the set of N ternary memory cells.

In one aspect, in the error-free case, the second binary sequence is a code word of a second error code.

In one aspect, the second error code has at least one

$$( {N}_{H} + {N}_{M}^{i} ) )$$

-from-N code, wherein

$${N}_{M}^{i}$$

is an i-th number of ternary values M in the N ternary memory cells.

If there is more than one value for i, the second error code is a multicode. If i is equal to 1, it is a

$$( {N}_{H} + {N}_{M}^{′} ) )$$

-from-N code, where

$${N}_{M}^{′}$$

is a number of ternary values M in the N memory cells.

In one aspect, in the error-free case, the third binary sequence is a code word of a third error code, wherein the third error code has at least one

$${N}_{M}^{i}$$

-from-(N-N_{H}) code.

In one aspect,
the first binary sequence is mapped one-to-one to MSBs,
the third binary sequence is mapped one-to-one to LSBs,
the composite binary value is determined from MSBs and LSBs.

In one aspect, the ternary symbols H are determined by a read-out in the time domain.

In one aspect, the ternary symbols M and L are determined by a comparison with a reference value.

A device is also provided for processing a value which is determined from a set of N ternary memory cells, wherein the device is configured to:
read out the set of ternary memory cells from a memory and determine the ternary symbol H, M or L contained in the respective ternary memory cell,
determining a first binary sequence based on the ternary symbols H of the set of read ternary memory cells,
determining a second binary sequence based on the ternary symbols H and M of the set of read ternary memory cells,
determine a third binary sequence based on the first binary sequence and the second binary sequence, wherein the number of bits of the third binary sequence is reduced compared with the number of bits of the first binary sequence and the second binary sequence,
determine a composite binary value based on the binary coded first binary sequence and the binary coded third binary sequence,
process the composite binary value.

In one aspect, the device is or comprises a circuit arrangement.

In one aspect, the memory is designed as part of the device or as separate from this device.

The above-described properties, features and advantages and the way in which they are achieved will be explained further in association with the following schematic description of exemplary embodiments which are explained in greater detail in association with the drawings. For the sake of clarity, identical or identically acting elements may be provided with identical reference signs.

### BRIEF DESCRIPTION OF THE DRAWINGS

In the drawings:

FIG. 1 shows an example of a schematic circuit for determining a third binary sequence from a first binary sequence and a second binary sequence, wherein the first and second binary sequences are based on ternary symbols read from ternary memory cells.

FIG. 2 shows a table illustrating a dependency between control signals c₁ to c₇ and bits x₁ to x₈ of the binary sequence X.

FIG. 3 shows a table of a possible implementation (“mapping rule”) of the bits x₁ to x₈ of the binary sequence X to 3 MSBs.

FIG. 4 shows a symbolic diagram having three frequency distributions for ternary symbols H, M and L over a cell current Icell.

### DESCRIPTION

As an example, ternary memory cells are considered below, wherein each of the ternary memory cells can store the different ternary symbols H, M and L.

During the read-out of a set of ternary memory cells, a mapping into binary values is performed by way of example. The further processing of binary values can be performed flexibly with conventional digital technology.

For example, the following steps can be carried out:
(1) reading out a plurality (e.g. a set or sequence) of ternary memory cells and determining the ternary symbol H, M or L contained in the respective ternary memory cell (or the physical value corresponding to the ternary symbol),
(2) determining a first binary sequence based on the ternary symbols from the read ternary memory cells, wherein the binary value 1 is assigned only to the ternary memory cell having the ternary symbol H, and the binary value 0 is assigned to the remaining ternary memory cells having either the ternary symbol M or the ternary symbol L,
(3) determining a second binary sequence based on the ternary symbols from the read ternary memory cells, wherein the binary value 1 is assigned to the ternary memory cells having the ternary symbol H or M, and the binary value 0 is assigned to the remaining ternary memory cells having the ternary symbol L,
(4) determining a third binary sequence based on the first binary sequence and the second binary sequence, the third binary sequence being determined from the bits of the second binary sequence at the position of which the bits of the first binary sequence are equal to 0, The third binary sequence is therefore reduced by a number of bits on which the first binary sequence is equal to 1.
(5) determining a composite binary value W based on a binary coding of the first binary sequence and a binary coding of the third binary sequence,
(6) processing the binary value W.

The third binary sequence can be determined from the second binary sequence by removing from the second binary sequence the bits for which the value 1 was determined in the first binary sequence. The bits of the third binary sequence correspond to the memory cells for which the ternary symbols M or L were determined during the read-out. The third binary sequence therefore has fewer bits than the first binary sequence and fewer bits than the second binary sequence.

Binary coding can be understood, for example, to mean the following: If n possible assignments exist for a sequence of m bits, the number n can be used to uniquely identify one of the assignments by establishing an assignment rule which assigns each of the values 1 to n to one of the possible assignments. The number n can then be binary coded, so that 2^{k}≥n applies. In this case, the binary coding can be performed with k bits. For example, a 1-from-9 code is determined by the fact there are precisely n=9 possible assignments for the m=9 bits. Four bits (24=16) are required for the binary coding of the numbers 1 to 9, wherein only 9 of the total of 16 possible states are required by the assignment rule.

In addition, it should be noted that the binary values 0 and 1 have been assigned here by way of example. In general, there are two different binary values, so that “0” represents the first binary value and “1” represents the second binary value. A dual description (swapping of 0 and 1) is correspondingly possible.

### Example: 8 Memory Cells

There are the ternary symbols H, M and L.

N=8 ternary memory cells are considered by way of example.

There are precisely 8 ways in which the 8 memory cells can be assigned with precisely one single symbol H: The symbol H can occur in each of the 8 memory cells.

The symbol M or the symbol L is stored in the remaining 7 memory cells.

A first value W₁ indicates the location of the 8 memory cells at which the symbol H is stored. The value range of W₁ extends from 0 to 7, wherein these 8 values can be (binary) coded with 3 bits (2³=8).

For each first value W₁ there are 27 possible assignments of the remaining 7 bits having the symbols M or L.

For example, during the read-out of the 8 memory cells, the sequence
M H M L L M L L
   is determined. The first binary sequence results in
01 0 0 0 0 0 0.

In the first binary sequence, a 1 appears only at the position of the symbol M, the symbols M and L otherwise being set to 0 for the first binary sequence.

The second binary sequence results in
1 1 1 0 0 1 0 0.

A 1 is set at the positions of the symbols H and M and a 0 is set at the positions of the symbols L.

The third binary sequence is determined based on the first binary sequence and the second binary sequence:
first binary sequence: 0100 0000
second binary sequence: 1110 0100
third binary sequence: 1.10 0100

The dot in the third binary sequence indicates that the second binary sequence is assumed, but one bit is omitted (the bit that is equal to 1 in the first binary sequence).

Thus, the third binary sequence has only 7 bits and reads: 1100100. The third binary sequence corresponds to a second value W₂.

In this example, the value W stored in the 10 (=7+3) memory cells is determined by

$$W = {W}_{1} \cdot {2}^{7} + {W}_{2} .$$

The value W₁ can be stored in three bits (three binary memory cells) and the value W₂ can be stored in seven bits (seven binary memory cells).

A different notation is:

$$W = {W}_{1} \vert {W}_{2} ,$$

where “|” means a chaining or concatenation of the two values W₁ and W₂.

The first value W₁ represents the three most significant bits (MSBs) and the second value W₂ represents the seven least significant bits (LSBs) of the value W.

### Example: 9 Memory Cells

N=9 ternary memory cells in which ternary symbols H, M and L can be stored are considered below.

For example, 2 symbols H, 4 symbols M and 3 symbols L are stored in the 9 ternary memory cells.

For example, during the read-out of the 9 ternary memory cells, the sequence
H M H L M L L M

is determined. The first binary sequence therefore results in
1 0 1 0 0 0 0 0 0.

A 1 is set only at the position of the symbol H, the symbols M and L otherwise being set to 0 for the first binary sequence. The 9 bits of the first binary sequence can be considered as a code word of a 2-from-9 code.

The second binary sequence results in
1 1 1 0 1 1 0 0 1.

A 1 is set at the positions of the symbols H and M. and a 0 is set at the positions of the symbols L. The bits in the second binary sequence are a code word of a 6-from-9 code.

The third binary sequence is formed using the bits of the second binary sequence at the position of which the bits of the first binary sequence are equal to 0:
first binary sequence: 1 0 1 0 0 0 0 0 0
second binary sequence: 1 1 1 0 1 1 0 0 1
third binary sequence: . 1 . 0 1 1 0 0 1

The dots in the third binary sequence indicate that one bit is omitted here (because in the first binary sequence it is equal to 1). Thus, the third binary sequence has only 7 bits and reads: 1011001. The bits in the third binary sequence are a code word of a 4-from-7 code.

### Determination of Ternary Symbols

It is an option for the bits of the first and second binary sequences to be determined in the time domain or to be determined in the time domain taking into account a sequence, as described, for example, in DE 10 2018 124 296 B4 or in U.S. Pat. No. 9,805,771.

It is also possible for the ternary symbols H to be determined in the time domain, i.e., for example, for the fastest 1 to be assigned to the ternary symbol H when reading a ternary cell. For example, a comparison can be made with respect to a predetermined set of cells (e.g. 8 cells): The ternary symbol H is assigned only to the cell that provides the highest cell current. For example, if there are 2 ternary symbols H for 8 cells, the ternary symbols H are assigned to the two cells (out of the 8 cells) that provide the highest cell current.

It is then determined for the remaining cells of the set of cells whether they should receive the ternary value M or the ternary value L. This is done, for example, by means of a threshold value comparison: The threshold value can be a reference current that is used, for example, for the set of cells. If the cell current is below the reference current, the ternary symbol L is assigned to the cell, otherwise (i.e. if the reference current is exceeded) the ternary symbol M is assigned to the cell.

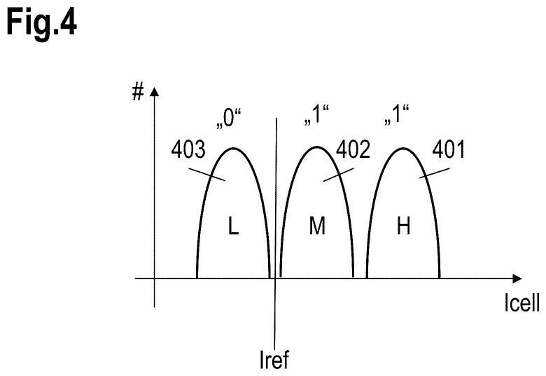

FIG. 4 shows a symbolic diagram having three frequency distributions 401 for the ternary symbol H, 402 for the ternary symbol M and 403 for the ternary symbol L over a cell current Icell. The frequency distribution 401 corresponds to the ternary symbol H, which, as explained above, for a set of (e.g. 8 or 9) ternary memory cells, determines the at least one ternary memory cell that provides the highest cell current. This can be done, for example, by comparing the set of read ternary memory cells in the time domain (highest current, e.g. cell current or read current of the read memory cell, is integrated and the cell with the highest read current is determined, i.e. the current that most quickly reaches a predetermined voltage during an integration, see, in particular, the above-mentioned prior art).

If the at least one ternary symbol H is determined, it is determined for the remaining ternary memory cells (of the set mentioned here) whether the ternary symbol L or the ternary symbol M was stored in them. This is done by comparison with a reference current Iref: if the cell current of the read ternary memory cell is less than the reference current Iref, the ternary symbol L is assigned to it, and if the cell current is larger than the reference current Iref, the ternary symbol M is assigned to it. It can be defined in advance whether the ternary symbol L or the ternary symbol M is assigned if the reference current Iref is equal.

### Mapping and Concatenation to a Value W.

To determine the first binary sequence, for example, the two fastest bits of the total of 9 bits can be determined. To determine the second binary sequence, the six fastest of the 9 bits can be determined. The bits of the third binary sequence form the bits of the second binary sequence, which are not the two fastest bits of the first binary sequence.

There are

$$( \begin{matrix}9 \\ 2\end{matrix} ) = 36 > {2}^{5}$$

different code words of the 2-from-9 code and therefore 36 different first binary sequences. Accordingly, there are

$$( \begin{matrix}7 \\ 4\end{matrix} ) = 35 > {2}^{5}$$

different code words of the 4-from-7 code and therefore 35 different third binary sequences.

A maximum of 10 bits can therefore be coded:

$${2}^{10} < 36 \cdot 35 = 1260 < {2}^{11} ,$$

if 2 memory cells store the ternary symbol H, 4 memory cells store the ternary symbol M and 3 memory cells store the ternary symbol L.

One option is to use only 32 of the 36 possible code words of the 2-from-9 code since 32 can be represented as the value W₁ by a five-digit binary value. These five bits are used as the MSB of the value W.

It is further an option to use only 32 of the 35 possible code words of the 4-from-7 code and to display the second value W₂ accordingly, similarly as a five-digit binary value. The second value W₂ is used as the LSB of the value W.

The stored value W results here in

$$W = {W}_{1} \vert {W}_{2} .$$

The readout of the 9 trivalent memory cells produces a mapping in the 10-bit value W with 5 MSBs and 5 LSBs.

Multicode with Different Ternary Symbols M

One option is to store a first ternary symbol H in a number NH of the N ternary memory cells, and to store a further number

$${N}_{M}^{1} or {N}_{M}^{2} or {N}_{M}^{3}$$

or a further number of ternary symbols M in the N-N_{H} memory cells in which the ternary symbol H is not stored. For example, a difference between the numbers of stored ternary symbols M can be at least equal to 2.

It is assumed below by way of example that the further numbers

$${N}_{M}^{1} , {N}_{M}^{2} and {N}_{M}^{3}$$

are used:

A code word of an N_{H}-from-N code is again determined as the first binary sequence.

Code words of an

$$( {N}_{H} + {N}_{M}^{1} ) )$$

-from-N code,

$$( {N}_{H} + {N}_{M}^{2} ) )$$

-from-N code, or

$$( {N}_{H} + {N}_{M}^{3} ) )$$

-from-N code
are determined as the second binary sequence. A code comprising a plurality of error codes can also be referred to as a multicode.

The third binary sequence comprises code words
of an

$${N}_{M}^{1} -$$

from-(N-N_{H}) code,
of an

$${N}_{M}^{2}$$

-from-(N—N_{H}) code and
of an

$${N}_{M}^{3}$$

-from-(N-N_{H}) code.

If, for example,

$$N = 9 , {N}_{H} = 1 , {N}_{M}^{1} = 1 , {N}_{M}^{2} = 3 , = {N}_{M}^{3} 5 , = {N}_{M}^{4} 7 ,$$

the bits of the first binary sequence form a code word of the 1-from-9 code, the bits of the second binary sequence form a code word of the 2-from-9 code or the 4-from-9 code or the 6-from-9 code or the 8-from-9 code. The bits of the third binary sequence form a code word of the 1-from-8 code, the 3-from-8 code, the 5-from-8 code, and the 7-from-8 code.
   Exemplary Embodiment with N=8

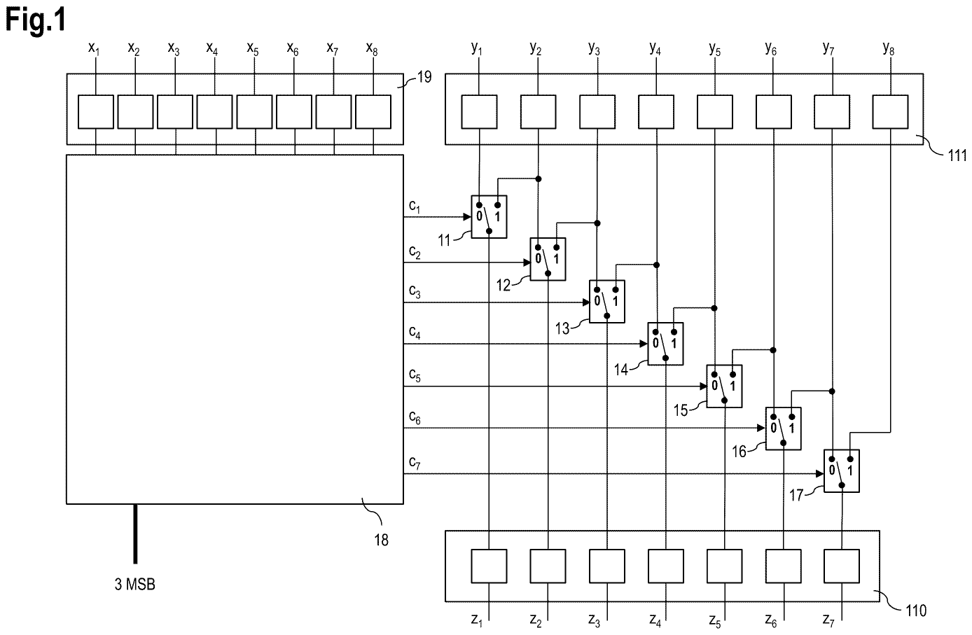

FIG. 1 shows an example of a schematic circuit for determining a third binary sequence from a first binary sequence and a second binary sequence. Here, for example, the number N of ternary memory cells N is equal to 8. During the readout of the ternary memory cells, a first binary sequence X is determined with the bits x₁ to x₈ and a second binary sequence Y with the bits y₁ to y₈, in each case with 8 bits.

During the readout of the ternary memory cells, a ternary symbol H and three ternary symbols M are determined for 8 ternary memory cells.

The binary sequence X (first binary sequence) thus represents one of the 8 possible code words of the 1-from-8 code, in which precisely one single bit is equal to 1 and all the other 7 bits are equal to 0.

Code words of a 4-from-8 code are determined as the binary sequence Y (second binary sequence). The 4 binary values 1 occur at the positions where the ternary memory cell has either the ternary symbol H or the ternary symbol M (but not the ternary symbol L). The binary sequence Y thus has 4 ones and 4 zeros.

The bits of a binary sequence Z (third binary sequence) are formed using the bits of the binary sequence Y at the position of which the bits of the binary sequence X are equal to 0. If the bit of the binary sequence X is equal to 1, it is omitted in the binary sequence Z. The binary sequence Z therefore has 7 bits.

An example of the assignment of the bits and the resulting binary sequence Z is as follows:
Binary sequence X: 0 1 0 0 0 0 0 0
Binary sequence Y: y₁ y₂ y₃ y₄ y₅ y₆ y₇ y₈
Binary sequence Z: y₁ y₃ y₄ y₅ y₆ y₇ y₈

In the formation of the binary sequence Z, the second bit y₂ of the binary sequence Y has thus been removed, since the bit of the binary sequence X is equal to 1 at this position.

FIG. 1 comprises a register 19 for storing the binary sequence X, a register 111 for storing the binary sequence Y and a register 110 for storing the binary sequence Z. FIG. 1 further shows seven multiplexers 11 to 17, each of which has a control input to connect either a 0 input or a 1 input to an output. A combinational circuit 18 is also provided which determines control signals c₁ to c₇ based on the bits x₁ to x₈ of the binary sequence X, each of which is applied to one of the control inputs of the multiplexers 11 to 17.

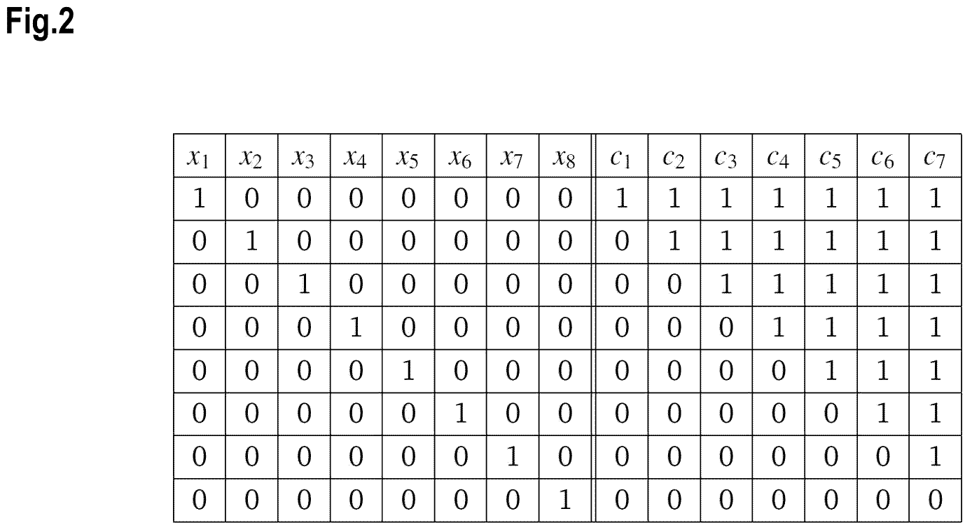

FIG. 2 shows a table illustrating the dependence of the control signals c₁ to c₇ on bits x₁ to x₈ of the binary sequence X. This dependency can be implemented, for example, by means of a combinational circuit 18.

The following applies, for example, with respect to the second row of the table with

$$X = 01000000$$

for the control signals c₁ to c₇
0 1 1 1 1 1 1.

The multiplexer 11 is thus connected to the input 0, the other multiplexers 12 to 17 being connected to the inputs 1. The value of the bit y₁ is provided as the first bit of the binary sequence Z at the output of multiplexer 11. The value of the bit y₃ is provided as the second bit of the binary sequence Z (the multiplexer 12 is connected to the input 1), etc. As a result, the value of the bit y₂ is therefore eliminated in the binary sequence Z.

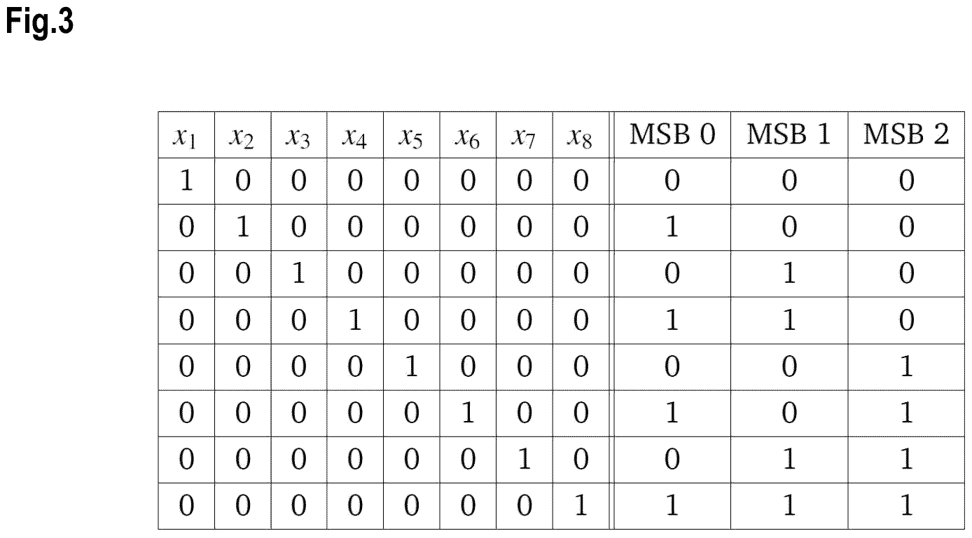

FIG. 3 shows a table of a possible implementation (“mapping rule”) of the bits x₁ to x₈ of the binary sequence X to 3 MSBs. Precisely 8 different binary sequences X exist, wherein a unique identification (or one-to-one assignment) of one of these binary sequences can be performed by means of three binary states. The combinational circuit 18 also provides this mapping rule for the 3 MSBs. This mapping rule can be implemented by means of a fixed programming (e.g. using a read-only memory) or a combinational circuit.

The bits of the binary sequence Z can form 35 different code words of the 3-from-7 code. If only 32 of the total of 35 possible code words are used, these 32 code words can be represented by means of 5 bits (i.e. with binary one-to-one coding), wherein each assignment of the 5 bits that is used identifies precisely one of the 32 code words). Such an implementation or mapping rule can also be realized by means of a fixed programming (e.g. using a read-only memory) or a combinational circuit.

This example therefore comprises 5 LSBs, which can be combined with the aforementioned 3 MSBs to form a value W. As a result, a selection of ternary values that can be stored in 8 ternary memory cells is mapped to binary values W, wherein each of the binary values has an MSB part with 3 bits and an LSB part with 5 bits.

Although the invention has been illustrated and described in greater detail based on the at least one exemplary embodiment shown, the invention is not restricted thereto and other variations can be derived therefrom by a person skilled in the art without departing the scope of protection of the invention.

What is claimed is:

1. A method for processing a value which is determined from a set of N ternary memory cells comprising:
reading out the set of ternary memory cells and determining the ternary symbol H, M or L contained in the respective ternary memory cell,
determining a first binary sequence based on the ternary symbols H of the set of read ternary memory cells,
determining a second binary sequence based on the ternary symbols H and M of the set of read ternary memory cells,
determining a third binary sequence based on the first binary sequence and the second binary sequence, wherein the number of bits of the third binary sequence is reduced compared with the number of bits of the first binary sequence and the second binary sequence,
determining a composite binary value based on the first binary sequence and the third binary sequence, and
processing the composite binary value.

2. The method of claim 1, wherein determining the first binary sequence comprises:
determining the first binary sequence, wherein the binary value 1 is assigned only to the ternary memory cell having the ternary symbol H, and the binary value 0 is assigned to the remaining ternary memory cells having either the ternary symbol M or the ternary symbol L.

3. The method of claim 1, wherein determining the second binary sequence comprises:
determining the second binary sequence, wherein the binary value 1 is assigned to the ternary memory cells having the ternary symbol H or the ternary symbol M, and the binary value 0 is assigned to the remaining ternary memory cells having the ternary symbol L.

4. The method of claim 1, wherein determining the third binary sequence comprises:
determining the third binary sequence, wherein the third binary sequence is determined from the bits of the second binary sequence at the position of which the bits of the first binary sequence are equal to 0.

5. The method of claim 1, wherein determining the third binary sequence comprises:
determining the third binary sequence by removing, from the second binary sequence, at least one bit for which the value 1 was determined in the first binary sequence.

6. The method of claim 1, wherein, in the error-free case, the first binary sequence is a code word of a first error code.

7. The method of claim 6, wherein the first error code is an N_{H}-from-N-code, wherein N_{H} is the number of ternary values H in the set of N ternary memory cells.

8. The method of claim 6, wherein, in the error-free case, the second binary sequence is a code word of a second error code.

9. The method of claim 8, wherein the second error code has at least one (N_{H}+N_M\hat{ }i))-from-N code, wherein
$${N}_{M}^{i}$$
is an i-th number of ternary values M in the N ternary memory cells.

10. The method of claim 9, wherein, in the error-free case, the third binary sequence is a code word of a third error code, wherein the third error code has at least one
$${N}_{M}^{i}$$
-from-(N—N_{H}) code.

11. The method of claim 1, wherein
the first binary sequence is mapped one-to-one to MSBs,
the third binary sequence is mapped one-to-one to LSBs, and
the composite binary value is determined from MSBs and LSBs.

12. The method of claim 1, wherein the ternary symbols H are determined by a readout in the time domain.

13. The method of claim 12, wherein the ternary symbols M and L are determined by a comparison with a reference value.

14. A device for processing a value determined from a set of N ternary memory cells, wherein the device is configured to
read out the set of ternary memory cells from a memory and determine the ternary symbol H, M or L contained in the respective ternary memory cell,
determine a first binary sequence based on the ternary symbols H of the set of read ternary memory cells,
determine a second binary sequence based on the ternary symbols H and M of the set of read ternary memory cells,
determine a third binary sequence based on the first binary sequence and the second binary sequence, wherein the number of bits in the third binary sequence is reduced compared with the number of bits in the first binary sequence and the second binary sequence,
determine a composite binary value based on the first binary sequence and the third binary sequence, and
process the composite binary value.

15. The device as of claim 14, wherein the memory is part of the device.

16. The device as of claim 14, wherein the memory is separate from this device.

17. A device, comprising:
a combinational circuit configured to generate n−1 control signals based on n binary values of a first binary sequence, wherein the first binary sequence is indicative of memory cells in a set of n memory cells storing the ternary symbol H; and
n−1 multiplexers, controlled by respective control signals to output selected bits of a second binary sequence comprising n binary values to generate a third binary sequence of n−1 values, wherein the second binary sequence is indicative of memory cells in the set of n memory cells storing either the ternary symbol H or the ternary symbol M,
wherein the device is configured to determine a composite binary value based on the first binary sequence and the third binary sequence.

18. The device of claim 17, wherein the combinational circuit generates the control signal such that the third binary sequence comprises the bits of the second binary sequence at positions corresponding to bits of the first binary sequence that are equal to 0.

19. The device of claim 17 wherein the combinational circuit generates the control signal such that at least one bit for which the value 1 was determined in the first binary sequence is removed from the second binary sequence.

20. The device of claim 17, wherein the device is configured to determine the composite binary value by
mapping the first binary sequence one-to-one to MSBs,
and mapping the third binary sequence one-to-one to LSBs, and
combining the MSBs and LSBs to determine the composite binary value.
